(19) United States
(12) Patent Application Publication
(10) Pub. No.: US 2021/0366945 A1
(43) Pub. Date: Nov. 25, 2021

(54) SEMICONDUCTOR DEVICE AND METHOD OF MANUFACTURING SEMICONDUCTOR DEVICE

(71) Applicant: Japan Display Inc., Tokyo (JP)

(72) Inventor: Takeshi SAKAI, Tokyo (JP)

(73) Assignee: Japan Display Inc., Tokyo (JP)

(21) Appl. No.: 17/397,251

(22) Filed: Aug. 9, 2021

Related U.S. Application Data
(63) Continuation of application No. PCT/JP2019/050580, filed on Dec. 24, 2019.

(30) Foreign Application Priority Data
Feb. 13, 2019 (JP) 2019-023649

(51) Int. Cl. H01L 27/12; H01L 29/786; H01L 21/02; H01L 29/66

(52) U.S. Cl. CPC H01L 27/1225; H01L 29/7869; H01L 29/66969; H01L 21/02565; H01L 27/127

(57) ABSTRACT

A semiconductor device includes a first circuit element, the first circuit element including: a first semiconductor layer having a concave part; a first insulating layer arranged above the first semiconductor layer, the first insulating layer having a first through hole in a region overlapping with the concave part. A method of manufacturing a semiconductor device, the method including: forming a first semiconductor layer having a concave part on a substrate; forming a first insulating layer on the first semiconductor layer; forming a first through hole in a region of the first insulating layer overlapping with the concave part; and forming a first conductive layer arranged in the concave part and the first through hole.

### CROSS REFERENCE TO RELATED APPLICATIONS

This application is based upon and claims the benefit of priority from the prior Japanese Patent Application No. 2019-023649, filed on Feb. 13, 2019, and PCT Application No. PCT/JP2019/050580, filed on Dec. 24, 2019, the entire contents of which are incorporated herein by reference.

### FIELD

The present invention relates to a semiconductor device and a method of manufacturing the semiconductor device. In particular, it relates to a structure of a semiconductor layer included in a semiconductor device.

### BACKGROUND

In recent years, semiconductor devices such as the transistor and diode have been used as the fine switching element for the driving circuit such as the display device and the personal computer. In particular, in the display device, the semiconductor device is used not only in the select transistor for supplying the voltage or current corresponding to the gradation of the light of each pixel but also in the drive transistor for selecting the pixel that supplies the voltage or current. Required characteristics of semiconductor devices are different depending on the application. For example, the semiconductor device used as the select transistor is required to have a lower off-current and a smaller variation in characteristics between semiconductor devices. The semiconductor device used as the drive transistor is required to have the higher on-current.

In the display device as described above, conventionally, semiconductor devices using amorphous silicon, low-temperature polysilicon, or single-crystal silicon as the channel have been developed. Since the semiconductor device using amorphous silicon or low-temperature polysilicon for the channel can be formed in the process of 600° C. or less, the semiconductor device can be formed using the glass substrate. In particular, the semiconductor device using amorphous silicon as the channel can be formed with a simpler structure and by a process of 400° C. or less. Therefore, for example, it can be formed using a large glass substrate called the eighth-generation (2160×2460 mm). However, the semiconductor device using amorphous silicon as the channel has low mobility and cannot be used for a drive transistor.

The semiconductor device using low-temperature polysilicon or single-crystal silicon as the channel has higher mobility than the semiconductor device using amorphous silicon as the channel. Therefore, the semiconductor device using low-temperature polysilicon or single-crystal silicon as the channel can be used not only for the select transistor but also for the drive transistor of the semiconductor device. However, the semiconductor device using low-temperature polysilicon or single-crystal silicon as the channels is complex in structure and process. These semiconductor devices cannot be formed using the large glass substrate as described above, because it needs 500° C. or higher to be processed. The semiconductor devices using amorphous silicon, low-temperature polysilicon, or single-crystal silicon as the channels have high off-current, so that it is difficult to hold the applied voltage for a long time when these semiconductor devices are used as the select transistor.

Therefore, recently, in place of amorphous silicon, low-temperature polysilicon, or single-crystal silicon, a semiconductor device using an oxide semiconductor as the channels has been developed (e.g., Japanese laid-open patent publication No. 2009-111125). The semiconductor device using the oxide semiconductor as the channels is able to form the semiconductor device in a simpler structure and low-temperature process similar to the semiconductor device using amorphous silicon as the channels. The semiconductor device using the oxide semiconductor as the channels is known to have a higher mobility than the semiconductor device using amorphous silicon as the channels. The semiconductor device using the oxide semiconductor as the channels is known to have extremely low off-current.

### SUMMARY

A semiconductor device according to an embodiment of the present invention includes a first circuit element, the first circuit element including: a first semiconductor layer having a concave part; a first insulating layer arranged above the first semiconductor layer, the first insulating layer having a first through hole in a region overlapping with the concave part; and a first conductive layer arranged in the concave part and the first through hole.

A method of manufacturing a semiconductor device according to an embodiment of the present invention includes: forming a first semiconductor layer having a concave part on a substrate; forming a first insulating layer on the first semiconductor layer; forming a first through hole in a region of the first insulating layer overlapping with the concave part; and forming a first conductive layer arranged in the concave part and the first through hole.

### BRIEF DESCRIPTION OF DRAWINGS

FIG. 1 is a plan view showing an overview of a semiconductor device according to an embodiment of the present invention;

FIG. 2 is a cross-sectional view showing an overview of a semiconductor device according to an embodiment of the present invention;

FIG. 3 is an enlarged cross-sectional view of a semiconductor device according to an embodiment of the present invention;

FIG. 4 is an enlarged cross-sectional view of a semiconductor device according to an embodiment of the present invention;

FIG. 5 is a cross-sectional view showing a process for forming a base layer in a method of manufacturing a semiconductor device according to an embodiment of the present invention;

FIG. 6 is a cross-sectional view showing a process for forming a semiconductor layer in a method of manufacturing a semiconductor device according to an embodiment of the present invention;

FIG. 7 is a cross-sectional view showing a process for forming a gate insulating layer and a gate electrode in a method of manufacturing a semiconductor device according to an embodiment of the present invention;

FIG. 8 is a cross-sectional view showing a process for doping a semiconductor layer with impurities in a method of manufacturing a semiconductor device according to an embodiment of the present invention;

FIG. 9 is a cross-sectional view showing a process for forming an interlayer insulating layer in a method of manufacturing a semiconductor device according to an embodiment of the present invention;

FIG. 10 is a cross-sectional view showing a process for forming an oxide semiconductor layer in a method of manufacturing a semiconductor device according to an embodiment of the present invention;

FIG. 11 is a cross-sectional view showing a process for forming a gate insulating layer and a gate electrode in a method of manufacturing a semiconductor device according to an embodiment of the present invention;

FIG. 12 is a cross-sectional view showing a process for doping an oxide semiconductor layer with impurities in a method of manufacturing a semiconductor device according to an embodiment of the present invention;

FIG. 13 is a cross-sectional view showing a process for forming an interlayer insulating layer in a method of manufacturing a semiconductor device according to an embodiment of the present invention;

FIG. 14 is a cross-sectional view showing a process for forming an opening in a method of manufacturing a semiconductor device according to an embodiment of the present invention;

FIG. 15 is a cross-sectional view showing a process for forming a barrier metal layer in a method of manufacturing a semiconductor device according to an embodiment of the present invention;

FIG. 16 is a cross-sectional view showing a process for forming a source electrode and drain electrode in a method of manufacturing a semiconductor device according to an embodiment of the present invention;

FIG. 17 is an enlarged cross-sectional view of a semiconductor device according to an embodiment of the present invention;

FIG. 18 is an enlarged cross-sectional view of a semiconductor device according to an embodiment of the present invention;

FIG. 19 is an enlarged cross-sectional view of a semiconductor device according to an embodiment of the present invention;

FIG. 20 is a cross-sectional view showing an overview of a semiconductor device according to an embodiment of the present invention;

FIG. 21 is a cross-sectional view showing an overview of a semiconductor device according to an embodiment of the present invention;

FIG. 22 is an enlarged cross-sectional view of a semiconductor device according to a modified example of the present invention;

FIG. 23 is an enlarged cross-sectional view of a semiconductor device according to a modified example of the present invention; and

FIG. 24 is an enlarged cross-sectional view of a semiconductor device according to a modified example of the present invention.

### DESCRIPTION OF EMBODIMENTS

Depending on a material contained in the semiconductor, increasing contact resistance with wirings is an issue. In view of the above-described circumstances, one of the objects of an embodiment of the present invention is to provide a semiconductor device that forms good contact between the semiconductor and wiring, and suppresses an increase in contact resistance by low manufacturing cost and simple process.

Hereinafter, some embodiments of the present invention will be described in detail with reference to the drawings. However, the present invention can be implemented in many different modes, and should not be construed as being limited to the description of the embodiments illustrated below.

For the sake of clarity of explanation, the drawings may be schematically represented with respect to widths, thicknesses, shapes, and the like of the respective portions in comparison with actual embodiments, but are merely examples and do not limit the interpretation of the present invention. For convenience of description, the dimensional ratio of the drawings may be different from the actual ratio, or a part of the configuration may be omitted from the drawings. In this specification and each of the drawings, the same elements as those described above with reference to the preceding drawings are denoted by the same reference numerals, and the detailed description thereof is omitted as appropriate.

In this specification, in a case where a plurality of films is formed by etching or irradiation with light with respect to one film, the plurality of films may have different functions and roles. However, these pluralities of films are derived from film formed as the same layer in the same process, and have the same layer structure and the same material. Therefore, the plurality of films is defined as being present in the same layer.

In this specification, when a member or region is “above (or below)” another member or region, unless otherwise limited, this includes not only being directly above (or below) another member or region, but also being above (or below) another member or region, i.e., including other components in between above (or below) another member or region.

In this specification, the phrase “one structure is exposed from another structure” means a mode in which a part of one structure is not covered by another structure, and the other part not covered by the structure includes a mode in which it is covered by still another structure.

### First Embodiment

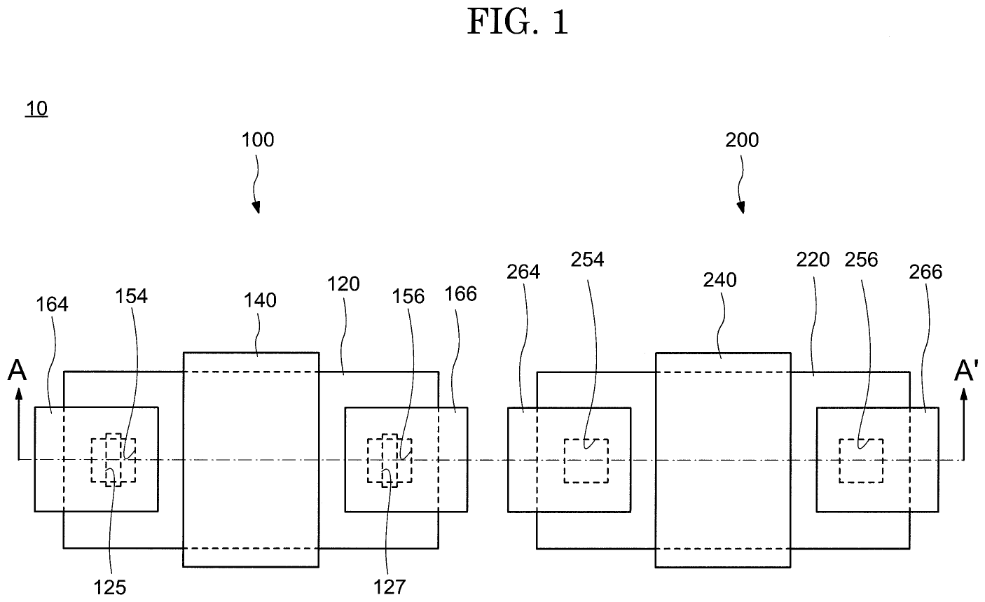

An overview of a semiconductor device 10 according to the first embodiment will be described with reference to FIGS. 1 to 16. The semiconductor device 10 of the first embodiment is used for each pixel of each display device, a select transistor, and a drive transistor in a liquid crystal display device (LCD), a self-luminous display device utilizing an a self-luminous element (Organic Light-Emitting Diode: OLED) such as organic EL element or a quantum-dot in the display unit, or in a reflective display device such as an electronic paper.

However, the present semiconductor device according to the present invention is not limited to that used for the display device, and may be used for, for example, an integrated circuit (IC) such as a micro-processing unit (MPU).

[Structure of Semiconductor Device 10]

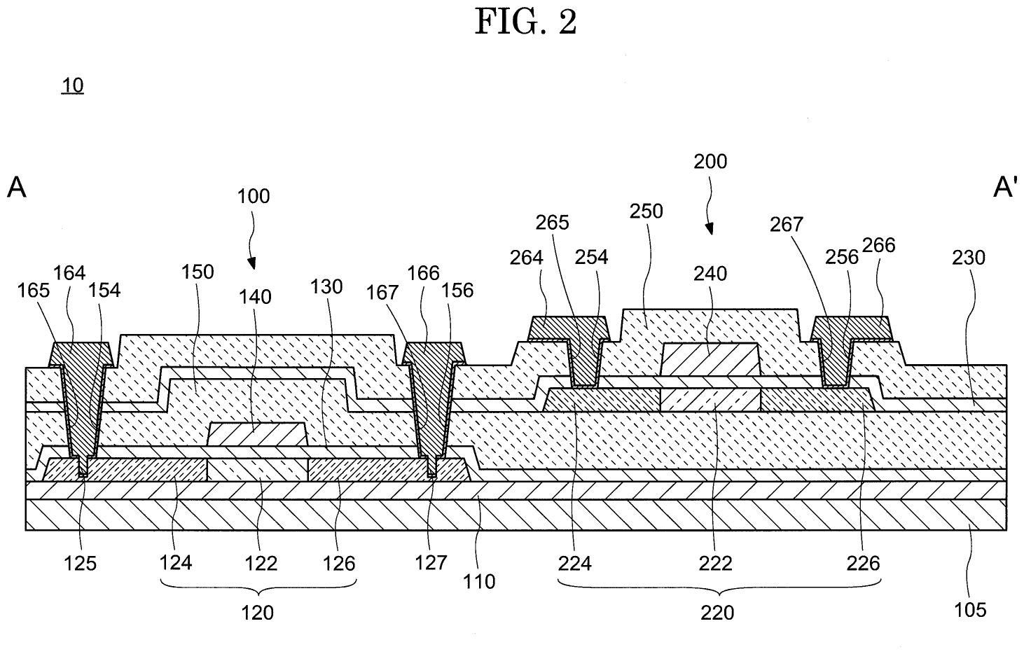

FIG. 1 is a plan view showing an overview of a semiconductor device according to an embodiment of the present invention. FIG. 2 is a cross-sectional view showing an overview of a semiconductor device according to an embodiment of the present invention. FIG. 2 is a A-A′ cross-sectional view in FIG. 1. As shown in FIGS. 1 and 2, the semiconductor device 10 has a first transistor element 100 and a second transistor element 200. Both the first transistor element 100 and the second transistor element 200 are arranged above a base layer 110 arranged on a substrate 105.

[Structure of First Transistor Element 100]

The first transistor element 100 has a first semiconductor layer 120, a first gate insulating layer 130, a first gate electrode 140, a first interlayer insulating layer 150, a first source electrode 164, and a first drain electrode 166. The first semiconductor layer 120 is arranged above the base layer 110. The first gate electrode 140 is arranged above the first semiconductor layer 120. The first gate insulating layer 130 is arranged between the first semiconductor layer 120 and the first gate electrode 140. The first semiconductor layer 120 includes a channel region 122, a source region 124, and a drain region 126. The channel region 122 is a region overlapped with the first gate electrode 140 in a plan view. The source region 124 and the drain region 126 are regions exposed from the first gate electrode 140 in a plan view.

The first transistor element 100 is a top-gate transistor in which the first gate electrode 140 is arranged above the first semiconductor layer 120. The resistance at the source region 124 and the drain region 126 of the semiconductor layer 120 is lower than the resistance at the channel region 122 of the first semiconductor layer 120 with no potential supplied to the first gate electrode 140. In other words, the electrical conductivity at the source region 124 and the drain region 126 of the first semiconductor layer 120 is higher than the electrical conductivity at the channel region 122 of the first semiconductor layer 120 with no potential supplied to the first gate electrode 140. In this embodiment, a material of the first semiconductor layer 120 includes low-temperature poly-silicon. However, the material of the first semiconductor layer 120 is not limited to this material, and the material may be any material other than an oxide semiconductor. For example, the material of the first semiconductor layer 120 may be amorphous silicon or single-crystal silicon. The source region 124 and the drain region 126 of the first semiconductor layer 120 contain more impurities than the channel region 122 of the first semiconductor layer 120. As the impurities contained in the first semiconductor layer 120, the materials used in the general semiconductor manufacturing processes, such as boron (B) and phosphorus (P), are used.

The first interlayer insulating layer 150 is arranged above the first gate electrode 140. The first interlayer insulating layer 150 covers the first semiconductor layer 120 and the first gate electrode 140. A second gate insulating layer 230 and a second interlayer insulating layer 250 are further arranged above the first interlayer insulating layer 150. The second gate insulating layer 230 and the second interlayer insulating layer 250 cover the first semiconductor layer 120 and the first gate electrode 140. The first gate insulating layer 130, the first interlayer insulating layer 150, the second gate insulating layer 230, and the second interlayer insulating layer 250 are provided with an opening 154 reaching the source region 124 of the first semiconductor layer 120, and an opening 156 reaching the drain region 126 of the first semiconductor layer 120. The first gate insulating layer 130, the first interlayer insulating layer 150, the second gate insulating layer 230, and the second interlayer insulating layer 250 expose the source region 124 and the drain region 126 of the first semiconductor layer 120 in the opening 154 and the opening 156. That is, the opening 154 and the opening 156 penetrate the first gate insulating layer 130, the first interlayer insulating layer 150, the second gate insulating layer 230, and the second interlayer insulating layer 250.

The first source electrode 164 and the first drain electrode 166 are arranged above the first interlayer insulating layer 150. Furthermore, the first source electrode 164 and the first drain electrode 166 are arranged in the opening 154 and the opening 156 of the first interlayer insulating layer 150, the first gate insulating layer 130, the second interlayer insulating layer 250, and the second gate insulating layer 230. The first source electrode 164 is connected to the source region 124 of the first semiconductor layer 120 via the opening 154. The first drain electrode 166 is connected to the drain region 126 of the first semiconductor layer 120 via the opening 156.

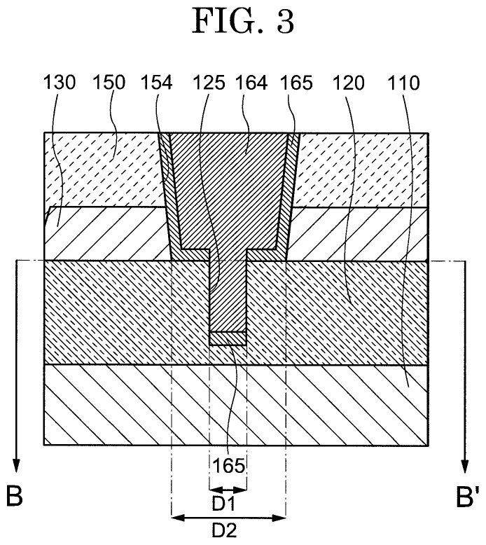

FIG. 3 shows an enlarged cross-sectional view of the connecting region between the source electrode 164 and the source region 124 of the first semiconductor layer 120. The connecting region between the first drain electrode 166 and the drain region 126 of the first semiconductor layer 120 has the same configuration, and the description thereof is omitted here. As shown in FIGS. 1 to 3, the first semiconductor layer 120 is provided with a concave part 125 in the source region 124, which is a connecting part with the first source electrode 164. The first semiconductor layer 120 is provided with a concave part 127 in the drain region 126, which is a connecting part with the first drain electrode 166. The opening 154 is arranged in a region overlapped with the concave part 125 of the first semiconductor layer 120. The opening 156 is arranged in a region overlapped with the concave part 127 of the first semiconductor layer 120. That is, the opening 154 and the opening 156 are at least partially connected to the concave part 125 and the concave part 127 at the bottom surface. The patterns of the concave part 125 and the concave part 127 will be described in detail later.

The first source electrode 164 and the first drain electrode 166 are arranged in the concave part 125 and the concave part 127 of the first semiconductor layer 120. The first source electrode 164 is connected to the source region 124 of the first semiconductor layer 120 via the concave part 125. The first drain electrode 166 is connected to the drain region 126 of the first semiconductor layer 120 via the concave part 127. Since the first semiconductor layer 120 has the concave part 125 and the concave part 127 at the connecting part with the first source electrode 164 and the first drain electrode 166, the contact area is increased, and better contacts can be formed between the first source electrode 164 and the source region 124 of the first semiconductor layer 120, and between the first drain electrode 166 and the drain region 126 of the first semiconductor layer 120. Further, since the first semiconductor layer 120 has the concave part 125 and the concave part 127, the physical connection strength between the first semiconductor layer 120 and each of the first source electrode 164 and the first drain electrode 166 can be improved, and the reliability of the first transistor element 100 can be further improved.

A barrier metal layer 165 and a barrier metal layer 167 are arranged between the first interlayer insulating layer 150, the first gate insulating layer 130, the second interlayer insulating layer 250, the second gate insulating layer 230, the first semiconductor 120, and the first source electrode 164, the first drain electrode 166. The barrier metal layer 165 is arranged in the opening 154. The barrier metal layer 167 is arranged in the opening 156. That is, the barrier metal layer 165 and the barrier metal layer 167 are arranged on the side surfaces and the bottom surfaces of the openings 154 and 156. The barrier metal layer 165 and the barrier metal layer 167 have the openings at the concave part 125 and the concave part 127 of the bottom surfaces of the opening 154 and the opening 156.

The barrier metal layer 165 and the barrier metal layer 167 are separated on the side surfaces of the concave part 125 and the concave part 127 of the first semiconductor layer 120. Additionally, the barrier metal layer 165 and the barrier metal layer 167 are arranged on the bottom surfaces of the concave part 125 and the concave part 127 of the first semiconductor layer 120. That is, the barrier metal layer 165 is discontinuous between the bottom surface of the opening 154 and the bottom surface of the concave part 125. The barrier metal layer 167 is discontinuous between the bottom surface of the opening 156 and the bottom surface of the concave part 127. The barrier metal layer 165 and the barrier metal layer 167 according to this embodiment are not arranged on the side surfaces of the concave part 125 and the concave part 127 of the first semiconductor layer 120. However, the present invention is not limited thereto, and the barrier metal layer 165 and the barrier metal layer 167 may be partially arranged on the side surfaces of the concave part 125 and the concave part 127 of the first semiconductor layer 120. The barrier metal layer 165 and the barrier metal layer 167 may be separated on the side surfaces of the concave part 125 and the concave part 127, and does not have to be arranged on the bottom surfaces of the concave part 125 and the concave part 127.

Since the barrier metal layer 165 is separated on the side surface of the concave part 125, the first source electrode 164 is in contact with the source region 124 of the first semiconductor layer 120 on the side surface of the concave part 125. Since the first source electrode 164 and the source region 124 are in direct contact with each other on the side surface of the concave part 125, it is possible to suppress an increase in the contact resistance between the first source electrode 164 and the source region 124 due to the presence of the barrier metal layer 165. Similarly, since the barrier metal layer 167 is separated on the side surface of the concave part 127, the first drain electrode 166 is in contact with the drain region 126 of the first semiconductor layer 120 on the side surface of the concave part 127. Since the first drain electrode 166 and the drain region 126 are in direct contact with each other on the side surface of the concave part 127, it is possible to suppress an increase in the contact resistance between the first drain electrode 166 and the drain region 126 due to the presence of the barrier metal layer 167.

[Patterns of Concave Part 125 and Concave Part 127]

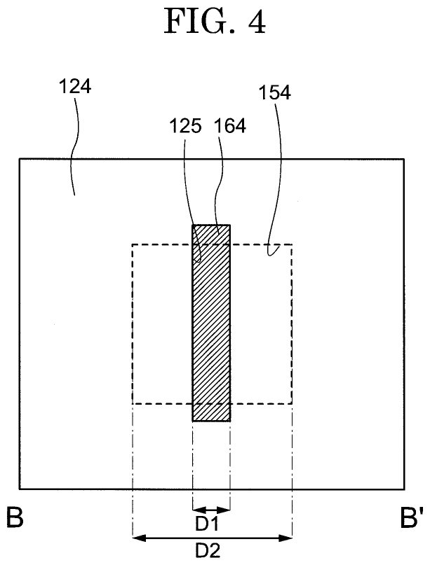

FIG. 4 is an enlarged cross-sectional view showing the concave part 125 of the first semiconductor layer 120 in the first transistor element 100. FIG. 4 shows a B-B′ cross-section in FIG. 3. Since the concave part 127 of the first semiconductor layer 120 has the same configuration, and the description thereof is omitted here. With reference to FIGS. 3 and 4, shapes of the opening 154 and the concave part 125 of the first semiconductor layer 120 in the first transistor element 100 will be described. The minimum diameter D1 at opening end portions of the concave part 125 and the concave part 127 are smaller than the minimum diameter D2 of the opening 154 and the opening 156. In this embodiment, the opening 154 and the opening 156 are tapered structures. For this reason, the opening 154 and the opening 156 have inclined surfaces on their side surfaces and have the minimum diameter D2 on the bottom surface (a region indicated by dotted lines). That is, the minimum diameter D1 at the opening end portions of the concave part 125 and the concave part 127 is smaller than the minimum diameter D2 at the bottom surfaces of the opening 154 and the opening 156. In this embodiment, the concave part 125 and the concave part 127 are structures in which steps between the opening end portions and the bottom surfaces are vertically connected to each other. Therefore, the concave part 125 and the concave part 127 have vertical surfaces on their side surfaces and have approximately the same diameter from the opening end portions to the bottom surfaces. However, the present invention is not limited thereto, and the concave part 125 and the concave part 127 may have tapered structures.

The minimum diameter D1 at the opening end portions of the concave part 125 and the concave part 127 is smaller than D2, more preferably 100 nm or more and less than the minimum diameter D2. If the minimum diameter D1 at the opening end portions of the concave part 125 and the concave part 127 is less than 100 nm or the minimum diameter D2 or more, the barrier metal layers 165, 167 may be continuously formed on the side surfaces and the bottom surfaces from the opening end portions of the concave part 125 and the concave part 127 in the process for forming the barrier metal layers 165, 167 to be described later, or, the first source electrode 164 and the first drain electrode 166 may not be arranged in the concave part 125 and the concave part 127 in the process for forming the first source electrode 164 and the first drain electrode 166 to be described later.

The depths of the concave part 125 and the concave part 127 in a film thickness direction of the first semiconductor layer 120 are preferably less than 50 nm. The depths of the concave part 125 and the concave part 127 in the film thickness direction of the first semiconductor layer 120 are 20% or more and less than 100%, preferably 50% or more and less than 100%, more preferably 90% or more and less than 100% with respect to the film thickness of the first semiconductor layer 120. When the depths of the concave part 125 and the concave part 127 are 10 nm or less, the barrier metal layers 165 and 167 may be continuously formed on the side surfaces and the bottom surfaces from the opening ends of the concave part 125 and the concave part 127 in the process for forming the barrier metal layers 165 and 167 to be described later. When the depths of the concave part 125 and the concave part 127 are 50 nm or more, the concave part 125 and the concave part 127 penetrate the first semiconductor layer 120 and may reach the base layer 110 and the substrate 105. However, the present invention is not limited thereto, and the concave part 125 and the concave part 127 may penetrate first semiconductor layer 120 and reach the base layer 110.

As shown in FIG. 4, the maximum diameter at the opening end portions of the concave part 125 and the concave part 127 is larger than the maximum diameter at the bottom surfaces of the opening 154 and the opening 156. However, the present invention is not limited thereto, the maximum diameter at the opening end portions of the concave part 125 and the concave part 127 may be smaller than the maximum diameter at the bottom surfaces of the opening 154 and the opening 156.

In this embodiment, the concave part 125 and the concave part 127 are arranged on the bottom surfaces of the opening 154 and the opening 156, respectively. However, the present invention is not limited thereto, and a plurality of the concave parts 125 and concave parts 127 may be arranged on the bottom surfaces of the opening 154 and the opening 156. In this embodiment, the concave part 125 and the concave part 127 are shown in line shapes. However, the present invention is not limited thereto, and the concave part 125 and the concave part 127 may have any shapes, and the plurality of the concave parts 125 and concave parts 127 may be partially connected.

[Structure of the Second Transistor Element 200]

The second transistor element 200 has a second semiconductor layer 220, the second gate insulating layer 230, a second gate electrode 240, the second interlayer insulating layer 250, a second source electrode 264, and a second drain electrode 266. The second semiconductor layer 220 is arranged above the base layer 110. The second semiconductor layer 220 is arranged above the first interlayer insulating layer 150. The second gate electrode 240 is arranged above the second semiconductor layer 220. The second gate insulating layer 230 is arranged between the second semiconductor layer 220 and the second gate electrode 240. The second semiconductor layer 220 includes a channel region 222, a source region 224, and a drain region 226. The channel region 222 is a region overlapped with the second gate electrode 240 in a plan view. The source region 224 and the drain region 226 are regions exposed from the second gate electrode 240 in a plan view.

The second transistor element 200 is a top-gate transistor in which the second gate electrode 240 is arranged above the second semiconductor layer 220. The resistance in the source region 224 and the drain region 226 of the second semiconductor layer 220 is lower than the resistance in the channel region 222 of the second semiconductor layer 220 with no potential supplied to the second gate electrode 240. In other words, the electrical conductivity of the second semiconductor layer 220 of the source region 224 and the drain region 226 of the second semiconductor layer 220 is higher than the electrical conductivity of the channel region 222 of the second semiconductor layer 220 with no potential supplied to the second gate electrode 240. In this embodiment, the material of the second semiconductor layer 220 includes an oxide semiconductor. The source region 224 and the drain region 226 of the second semiconductor layer 220 contain more impurities than the channel region 222 of the second semiconductor layer 220. As the impurities contained in the second semiconductor layer 220, the materials used in the general semiconductor manufacturing processes, such as boron (B), phosphorus (P), argon (Ar), and nitrogen (N₂), are used.

The second interlayer insulating layer 250 is arranged above the second gate electrode 240. The second interlayer insulating layer 250 covers the second semiconductor layer 220 and the second gate electrode 240. The second gate insulating layer 230 and the second interlayer insulating layer 250 are provided with an opening 254 reaching the source region 224 of the second semiconductor layer 220 and an opening 256 reaching the drain region 226 of the second semiconductor layer 220. That is, the second gate insulating layer 230 and the second interlayer insulating layer 250 expose the source region 224 and the drain region 226 of the second semiconductor layer 220 in the opening 254 and the opening 256.

The second source electrode 264 and the second drain electrode 266 are arranged above the second interlayer insulating layer 250. The second source electrode 264 and the second drain electrode 266 are arranged in the opening 254 and the opening 256 of the second interlayer insulating layer 250 and the second gate insulating layer 230. The second source electrode 264 is connected to the source region 224 of the second semiconductor layer 220 via the opening 254. The second drain electrode 266 is connected to the drain region 226 of the second semiconductor layer 220 via the opening 256.

A barrier metal layer 265 and a barrier metal layer 267 are arranged between the second interlayer insulating layer 250, the second gate insulating layer 230, the second semiconductor layer 220, and the second source electrode 264, the second drain electrode 266. The barrier metal layer 265 is arranged in the opening 254. The barrier metal layer 267 is arranged in the opening 256. That is, the barrier metal layer 265 and the barrier metal layer 267 are arranged on the side surfaces and the bottom surfaces of the opening 254 and the opening 256.

Since the barrier metal layer 265 is arranged on the bottom surface of the opening 254, the second source electrode 264 is connected to the source region 224 of the second semiconductor layer 220 via the barrier metal layer 265 at the bottom surface of the opening 254. Since the second source electrode 264 is connected to the second semiconductor layer 220 via the barrier metal layer 265, it is possible to suppress the formation of an oxide film that may occur due to the direct contact with the second source electrode 264 and the second semiconductor layer 220 including the oxide semiconductor, thereby it is possible to suppress an increase in the contact resistance. Similarly, since the barrier metal layer 267 is arranged on the bottom surface of the opening 256, the second drain electrode 266 is connected to the drain region 226 of the second semiconductor layer 220 via the barrier metal layer 267 at the bottom surface of the opening 256. Since the second drain electrode 266 is connected to the second semiconductor layer 220 via the barrier metal layer 267, it is possible to suppress the formation of an oxide film that may occur due to direct contact with the second drain electrode 266 and the second semiconductor layer 220 including the oxide semiconductor, thereby it is possible to suppress an increase in the contact resistance.

[Material of Each Member Constituting Semiconductor Device 10]

A polyimide substrate is used as the substrate 105. An insulating substrate containing a resin such as an acrylic substrate, a siloxane substrate, or a fluororesin substrate may be used as the substrate 105 in addition to the polyimide substrate. Impurities may be introduced into the above substrate to improve the heat resistance of the substrate 105. In particular, when the semiconductor device 10 is a top-emission type display, since the substrate 105 does not need to be transparent, impurities that deteriorates the transparency of the substrate 105 may be used. On the other hand, when the substrate 105 does not need to have flexibility, an insulating substrate having light transmittance such as a glass substrate, a quartz substrate, and a sapphire substrate may be used as the substrate 105. In the case of an integrated circuit where the semiconductor device 10 is not the display device, a non-light transmittance substrate such as a semiconductor substrate like a silicon display device, a silicon carbide substrate, or a compound semiconductor substrate or such as a conductive substrate like a stainless substrate may be used.

A material that improves the adhesion between the substrate 105 and the first semiconductor layer 120 or suppresses the impurities from the substrate 105 from reaching the first semiconductor layer 120 is used as the base layer 110. For example, the base layer 110 may be made of, for example, silicone oxide (SiOₓ), silicone oxide nitride (SiOₓN_{y}), silicon nitride oxide (SiNₓO_{y}), silicon nitride (SiNₓ), aluminum oxide (AlOₓ), aluminum oxide nitride (AlOₓN_{y}), aluminum nitride oxide (AlNₓO_{y}), or aluminum nitride (AlNₓ) (x and y are any positive values). A structure in which these films are stacked may be used. Here, when a sufficient adhesion between the substrate 105 and the first semiconductor layer 120 is ensured, or when there is almost no effect of impurities reaching the first semiconductor layer 120 from the substrate 105, the base layer 110 may be omitted. A TEOS layer or an organic insulating material layer may be used as the base layer 110 in addition to the above inorganic insulating material layers.

Here, SiOₓN_{y} and AlOₓN_{y} are a silicone compound and an aluminum compound both containing a lower amount of nitrogen (N) than that of oxygen (O). SiNₓO_{y} and AlNₓO_{y} are a silicone compound and an aluminum compound both containing a lower amount of oxygen than that of nitrogen.

The base layer 110 illustrated above may be formed by physical vapor deposition (PVD method) or chemical vapor deposition (CVD method). As the PVD method, a sputtering method, a vacuum deposition method, an electron beam evaporation method, a plating method, and a molecular beam epitaxy method, and the like are used. As the CVD method, a thermal CVD method, a plasma CVD method, a catalytic CVD method (Cat-CVD method or hot wire CVD method), and the like are used. The TEOS layer refers to a CVD layer using TEOS (Tetra Ethyl Ortho Silicate) as a raw material.

As the organic insulating material, a polyimide resin, an acrylic resin, an epoxy resin, a silicone resin, a fluororesin, a siloxane resin, and the like are used. The base layer 110 may be a single layer or a stack of the materials described above. For example, the base layer 110 may be a stack of an inorganic insulating material and an organic insulating material.

As the first semiconductor layer 120, silicon having semiconductor characteristics is used. For example, polysilicon (polycrystalline silicon), amorphous silicon, single crystal silicon may be used as the first semiconductor layer 120. In particular, low-temperature polysilicon that does not require a high-temperature treatment may be used as the first semiconductor layer 120.

A metal oxide having semiconductor characteristics is used as the second semiconductor layer 220 including an oxide semiconductor. For example, an oxide semiconductor containing indium (In), gallium (Ga), zinc (Zn), and oxygen (O) may be used as the second semiconductor layer 220. In particular, an oxide semiconductor having a composition ratio of In:Ga:Zn:0=1:1:1:4 may be used as the second semiconductor layer 220. However, the oxide semiconductor containing In, Ga, Zn, and O used in an embodiment of the present invention is not limited to the above composition, and an oxide semiconductor having a composition different from the above composition may be used. For example, an oxide semiconductor having a larger in ratio than the above ratio may be used as the second semiconductor layer 220 in order to improve mobility. To reduce the effect of the light irradiation, an oxide semiconductor having a larger Ga ratio than the above ratio may be used as the second semiconductor layer 220 so that the band-gap becomes large.

Other elements may be added to the oxide semiconductor containing In, Ga, Zn, and O. For example, a metal element such as Al or Sn may be added to the above oxide semiconductor. In addition to the above oxide semiconductor, zinc oxide (ZnO), nickel oxide (NiO), tin oxide (SnO₂), titanium oxide (TiO₂), vanadium oxide (VO₂), indium oxide (In₂O₃), strontium titanate (SrTiO₃), and the like are may also be used as the semiconductor layer 220. The second semiconductor layer 220 may be amorphous and may be crystalline. The second semiconductor layer 220 may be a mixed phase of amorphous and crystalline.

As the first gate insulating layer 130 and the second gate insulating layer 230, an inorganic insulating material such as SiNₓ, SiNₓO_{y}, SiOₓN_{y}, AlNₓ, AlNₓ O_{y}, AlOₓN_{y} is used. The first gate insulating layer 130 and the second gate insulating layer 230 are formed in the same method as the base layer 110. The first gate insulating layer 130 and the second gate insulating layer 230 may be a single layer or may be a stack of the materials described above. The first gate insulating layer 130 and the second gate insulating layer 230 may be made of the same material as the base layer 110 or a different material.

Common metal materials or conductive semiconducting materials are used as the first gate electrode 140 and the second gate electrode 240. For example, aluminum (Al), titanium (Ti), chromium (Cr), cobalt (Co), nickel (Ni), zinc (Zn), molybdenum (Mo), indium (In), tin (Sn), hafnium (Hf), tantalum (Ta), tungsten (W), platinum (Pt), bismuth (Bi), and the like are used as the first gate electrode 140 and the second gate electrode 240. An alloy of the above materials and nitrides of the above materials may be used as the first gate electrode 140 and the second gate electrode 240. A conductive oxide semiconductor such as an ITO (indium tin oxide), an IGO (indium gallium oxide), an IZO (indium zinc oxide), or a GZO (zinc oxide doped with gallium) may be used as the first gate electrode 140 and the second gate electrode 240. The first gate electrode 140 and the second gate electrode 240 may be a single layer or may be a stack of the materials described above.

The material used as the first gate electrode 140 and the second gate electrode 240 is preferably a material having heat resistance to a heat treatment process in the manufacturing process of the semiconductor device using an oxide semiconductor as the channels. A material having a work function that becomes an enhancement type in which the transistor is turned off when 0V is applied to the first gate electrode 140 and the second gate electrode 240 is preferably used as the first gate electrode 140 and the second gate electrode 240.

An inorganic insulating material such as a SiOₓ, SiOₓN_{y}, AlOₓ, AlOₓN_{y}, TEOS layer is used as the first interlayer insulating layer 150 and the second interlayer insulating layer 250. The first interlayer insulating layer 150 and the second interlayer insulating layer 250 may be formed in the same method as the base layer 110. The first interlayer insulating layer 150 and the second interlayer insulating layer 250 may be a single layer or may be a stack of the materials described above. The first interlayer insulating layer 150 and the second interlayer insulating layer 250 may contain more oxygen than the stoichiometric ratio of the materials used as the first interlayer insulating layer 150 and the second interlayer insulating layer 250.

Common metal materials are used as the first source electrode 164, the first drain electrode 166, the second source electrode 264, and the second drain electrode 266. For example, Al, Ti, Cr, Co, Ni, Zn, Mo, In, Sn, Hf, Ta, W, Pt, Bi, and the like may be used as the above electrodes. The above electrodes may be a single layer or a stack of the above materials. The material used as the above electrodes is preferably a material having heat resistance to the heat treatment process in the manufacturing process of the semiconductor device using an oxide semiconductor as the channels.

Nitrides of the materials of the first source electrode 164, the first drain electrode 166, the second source electrode 264, and the second drain electrode 266 may be used as the barrier metal layers 165, 167, 265, and 267. For example, when a stack of Ti—Al—Ti is used as a material for the first source electrode 164, the first drain electrode 166, the second source electrode 264, and the second drain electrode 266, TiN may be used as a material for the barrier metal layers 165, 167, 265, and 267. Since TiN is used as the material of the barrier metal layers 265 and 267, it is possible to suppress the formation of an oxide film and the like that may occur due to the direct contact with Ti of the second source electrode 264 and the second drain electrode 266 and the second semiconductor layer 220 including an oxide semiconductor, thereby it is possible to suppress an increase in the contact resistance.

As described above, in the semiconductor device 10 according to the first embodiment of the present invention, since the first transistor element 100 and the second transistor element 200 using different semiconductors can be formed by a simple process, it is possible to provide the semiconductor device with low manufacturing costs and improved manufacturing yields. As a result, it is possible to provide, for example, the semiconductor device in which the select transistor using an oxide semiconductor with a lower off-current and the drive transistor using low-temperature polysilicon with high mobility are mounted in a mixed manner, and it is possible to successfully utilize both the characteristics of the oxide semiconductor and low-temperature polysilicon.

The contact area is increased by having the concave part 125 and the concave part 127 at the connecting part between the first semiconductor layer 120 and each of the first source-electrode 164 and the first drain electrode 166, and better contacts can be formed. Since the first semiconductor layer 120 has the concave part 125 and the concave part 127, it is possible to improve the physical connection strength between the first semiconductor layer 120 and the first source electrode 164, the first drain electrode 166, and the reliability of the first transistor element 100 can be further improved.

Since the second semiconductor layer 220 is connected via the barrier metal layer 265 and the barrier metal layer 267 at the connecting part with the second source electrode 264 and the second drain electrode 266, it is possible to suppress the formation of an oxide film and the like that may occur due to the direct contact with the second semiconductor layer 220 including an oxide semiconductor and each of the second source electrode 264 and the second drain electrode 266, thereby it is possible to suppress an increase in the contact resistance.

[Method of Manufacturing Semiconductor Device 10]

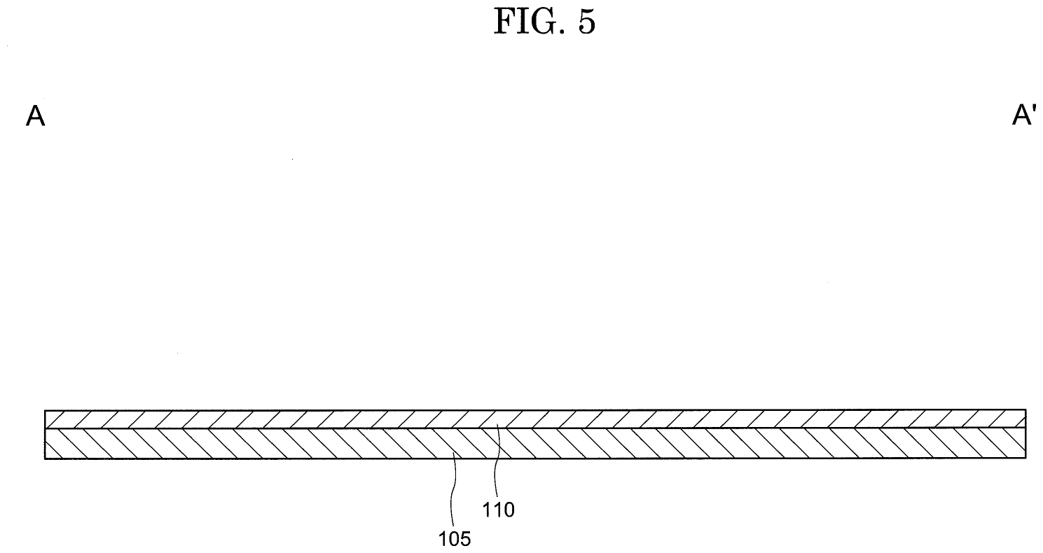

Referring to FIGS. 5 to 16, a method of manufacturing the semiconductor device 10 according to the first embodiment of the present invention will be described with reference to cross-sectional views. FIG. 5 is a cross-sectional view showing a process for forming a base layer in a method of manufacturing a semiconductor device according to an embodiment of the present invention. As shown in FIG. 5, the base layer 110 is formed on the substrate 105.

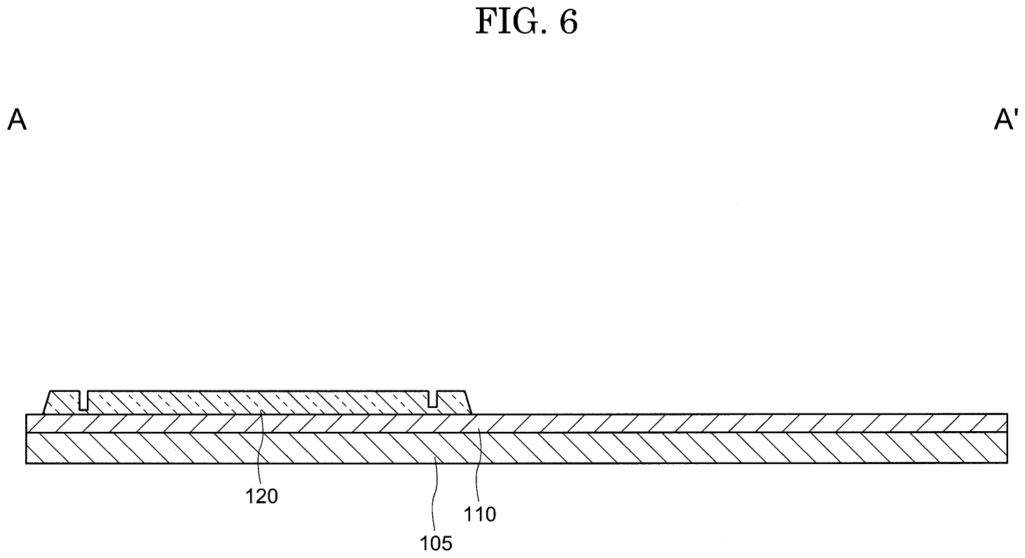

FIG. 6 is a cross-sectional view showing a process for forming a semiconductor layer in a method of manufacturing a semiconductor device according to an embodiment of the present invention. First, an amorphous silicon layer is formed on substantially the entire surface of the substrate, and the amorphous silicon layer is annealed from an amorphous (non-crystalline) state to a poly (polycrystalline) state by a laser irradiation. Thereafter, as shown in FIG. 6, a pattern of the first semiconductor layer 120 including the concave part 125 and the concave part 127 is formed by photolithography and etching.

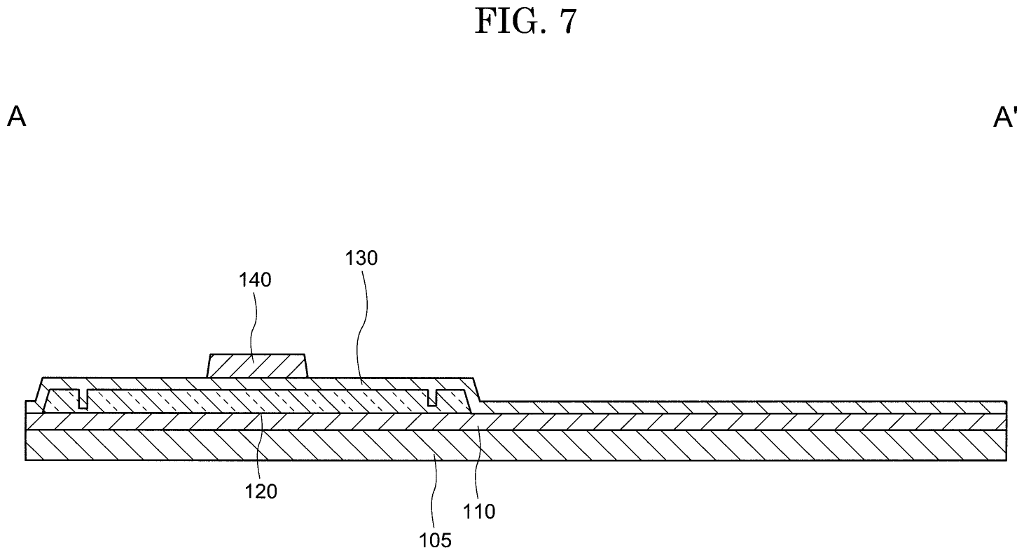

FIG. 7 is a cross-sectional view showing a process for forming a gate insulating layer and a gate electrode in a method of manufacturing a semiconductor device according to an embodiment of the present invention. As shown in FIG. 7, the first gate insulating layer 130 and a conductive layer including the first gate electrode 140 are formed above the first semiconductor layer 120, and form a pattern of the first gate electrode 140 as shown in FIG. 7 by photolithography and etching. In this case, the first gate insulating layer 130 is temporarily arranged in the concave part 125 and the concave part 127 of the first semiconductor layer 120.

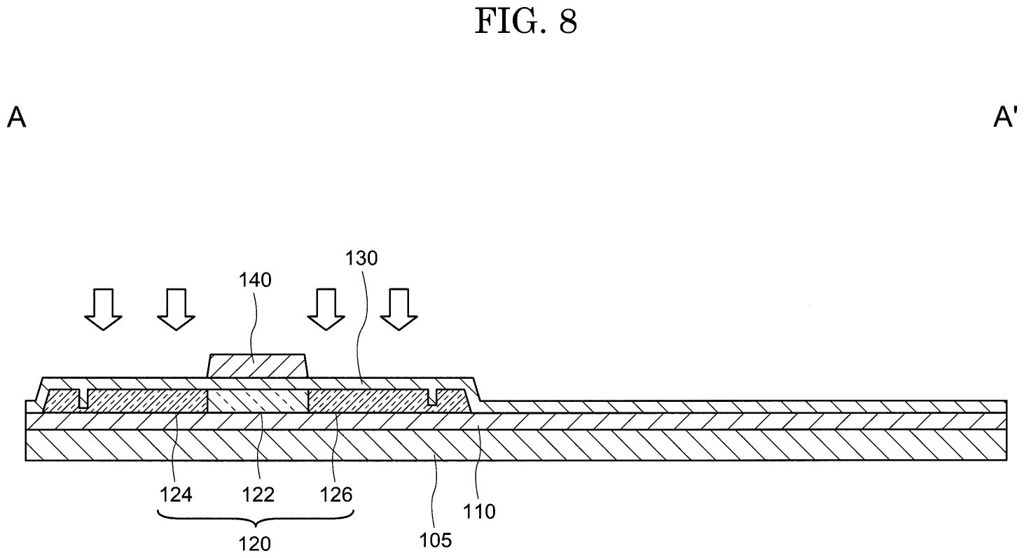

FIG. 8 is a cross-sectional view showing a process for doping a semiconductor layer with impurities in a method of manufacturing a semiconductor device according to an embodiment of the present invention. Impurities are doped from above (the side where the first gate electrode 140 is formed with respect to the substrate 105) as shown in FIG. 8. In a region that does not overlap with the first gate electrode 140 in a plan view, the impurities reach the first semiconductor layer 120 via the first gate insulating layer 130. Since the impurities doped in the first semiconductor layer 120 function as a carrier, the resistance of the first semiconductor layer 120 in the region doped with the impurities is reduced.

On the other hand, in a region that overlaps with the first gate electrode 140 in a plan view, since the impurities are blocked by the first gate electrode 140, the impurities do not reach the first semiconductor layer 120. That is, by doping the impurities via the first gate electrode 140, the channel region 122, and the source region 124 and the drain region 126 with lower resistance than the channel region 122 are formed on the first semiconductor layer 120.

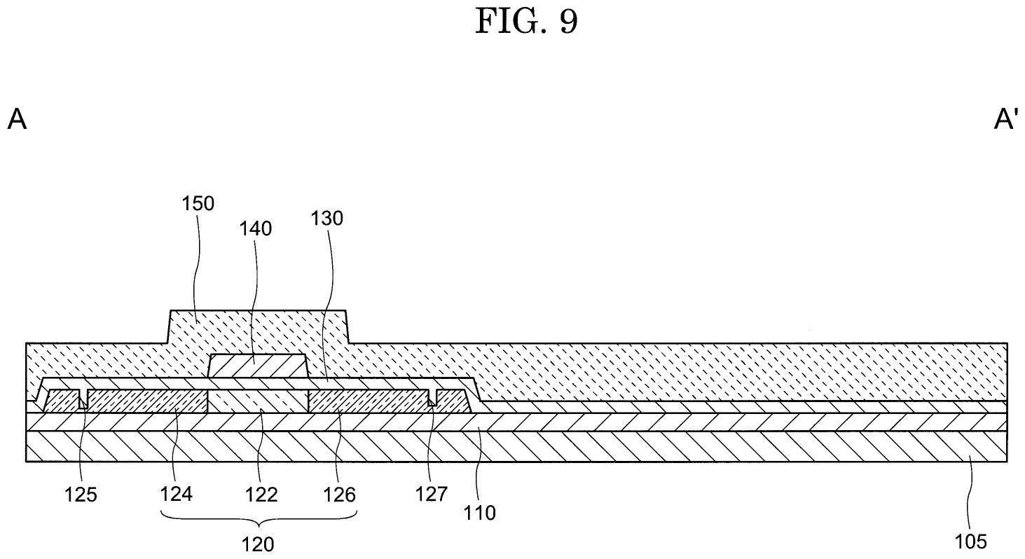

FIG. 9 is a cross-sectional view showing a process for forming an interlayer insulating layer in a method of manufacturing a semiconductor device according to an embodiment of the present invention. As shown in FIG. 9, the first interlayer insulating layer 150 that covers the first gate electrode 140 and the first semiconductor layer 120 is formed above the first gate electrode 140.

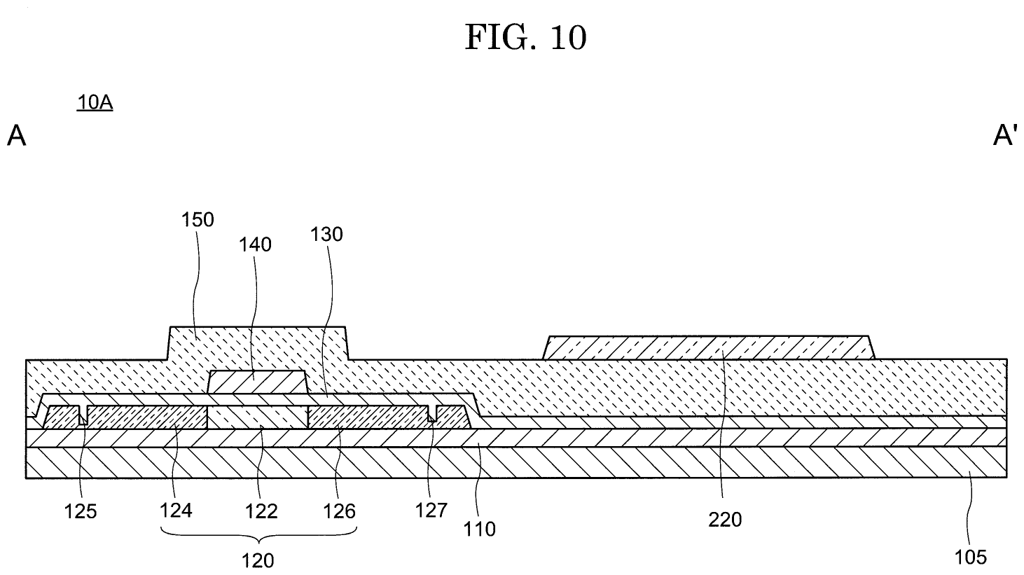

FIG. 10 is a cross-sectional view showing a process for forming a semiconductor layer in a method of manufacturing a semiconductor device according to an embodiment of the present invention. As shown in FIG. 10, an oxide semiconductor layer including the second semiconductor layer 220 is formed on substantially the entire surface of the substrate, and form a pattern of the second semiconductor layer 220 by photolithography and etching.

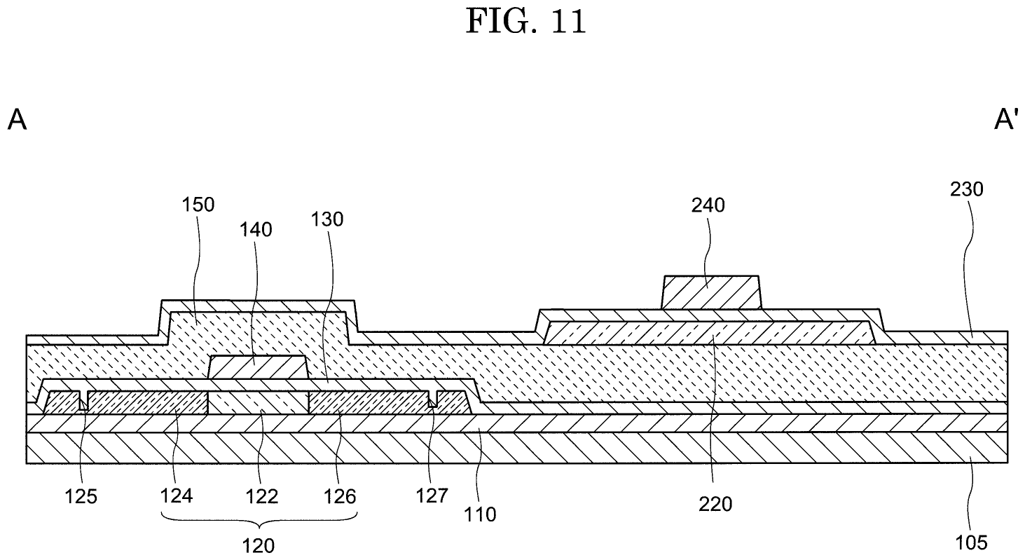

FIG. 11 is a cross-sectional view showing a process for forming a gate insulating layer and a gate electrode in a method of manufacturing a semiconductor device according to an embodiment of the present invention. As shown in FIG. 11, the second gate insulating layer 230 and a conductive layer including the second gate electrode 240 are formed above the second semiconductor layer 220, and form a pattern of the second gate electrode 240 as shown in FIG. 11 by photolithography and etching.

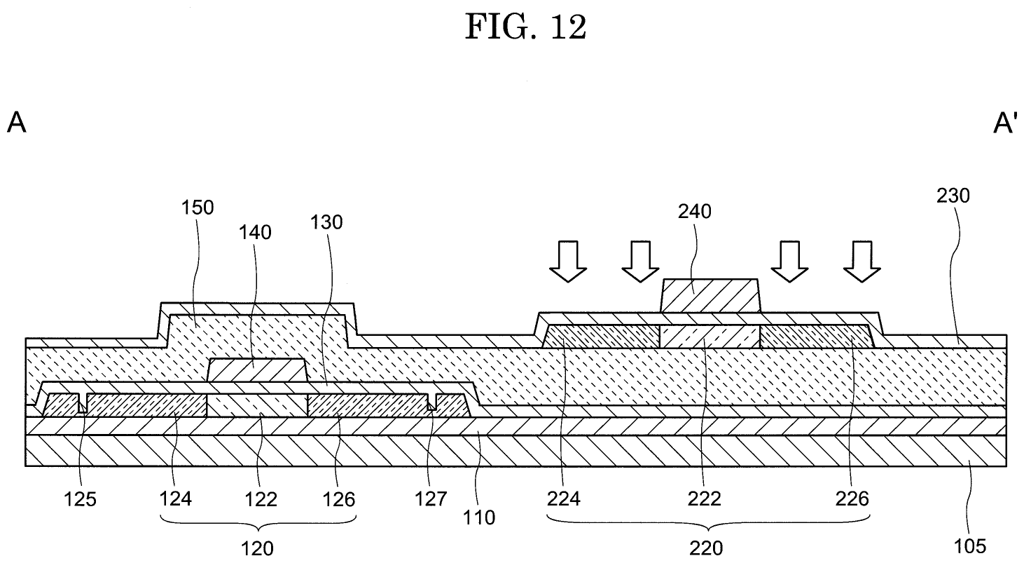

FIG. 12 is a cross-sectional view showing a process for doping a semiconductor layer with impurities in a method of manufacturing a semiconductor device according to an embodiment of the present invention. Impurities are doped from the above (the side where the second gate electrode 240 is formed with reference to the substrate 105) as shown in FIG. 12. In a region that does not overlap the second gate electrode 240 in a plan view, the impurities reach the second semiconductor layer 220 via the second gate insulating layer 230. When the second semiconductor layer 220 is doped with impurities, the crystal structure of the second semiconductor layer 220 in the region doped with impurities is broken and the resistance is reduced.

On the other hand, in a region that overlaps with the second gate electrode 240 in a plan view, since the impurities are blocked by the second gate electrode 240, the impurities do not reach the second semiconductor layer 220. That is, by doping the impurities via the second gate electrode 240, the channel region 222, and the source region 224 and the drain region 226 with lower resistance than the channel region 222 are formed on the second semiconductor layer 220.

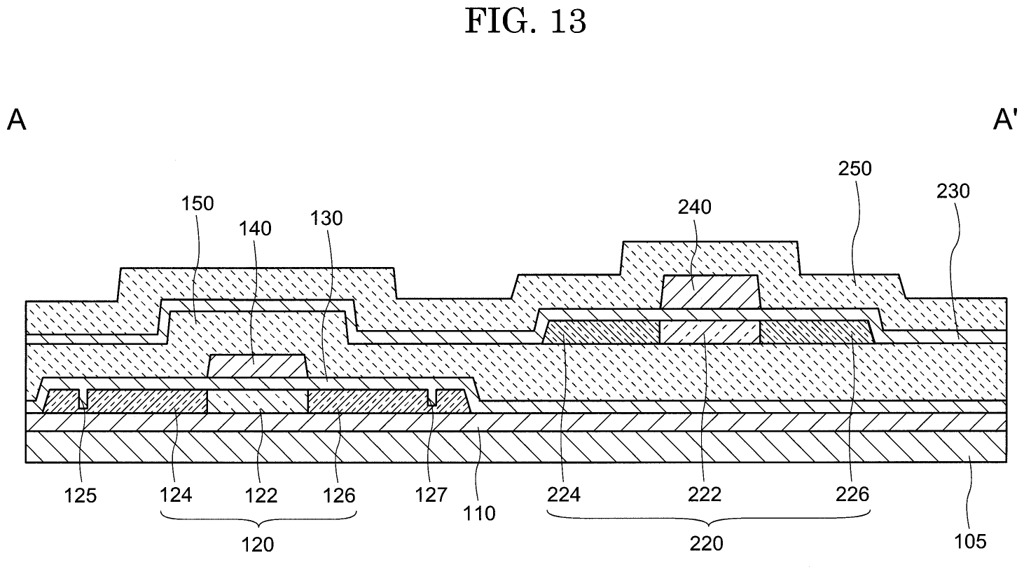

FIG. 13 is a cross-sectional view showing a process for forming an interlayer insulating layer in a method of manufacturing a semiconductor device according to an embodiment of the present invention. As shown in FIG. 13, the second interlayer insulating layer 250 that covers the second gate electrode 240 and the second semiconductor layer 220 is formed above the second gate electrode 240.

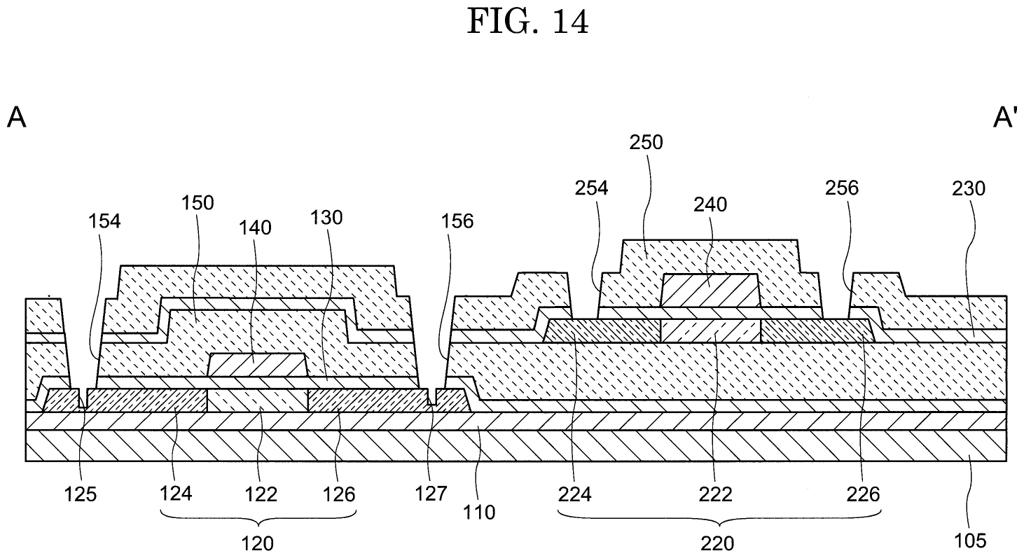

FIG. 14 is a cross-sectional view showing a process for forming an opening in a method of manufacturing a semiconductor device according to an embodiment of the present invention. The openings 154, 156, 254, and 256 are formed by photolithography and etching the first gate insulating layer 130, the first interlayer insulating layer 150, the second gate insulating layer 230, and the second interlayer insulating layer 250. The openings 154 and 156 are formed in the first gate insulating layer 130, the first interlayer insulating layer 150, the second gate insulating layer 230, and the second interlayer insulating layer 250. The openings 254 and 256 are formed in the second gate insulating layer 230 and the second interlayer insulating layer 250. At this time, the first gate insulating layer 130, which was temporarily arranged in the concave part 125 and the concave part 127 of the first semiconductor layer 120, is also etched together with the first gate insulating layer 130 of the openings 154 and 156.

The opening 154 exposes the source region 124 of the first semiconductor layer 120. The opening 156 exposes the drain region 126 of the first semiconductor layer 120. The opening 254 exposes the source region 224 of the second semiconductor layer 220. The opening 256 exposes the drain region 226 of the second semiconductor layer 220.

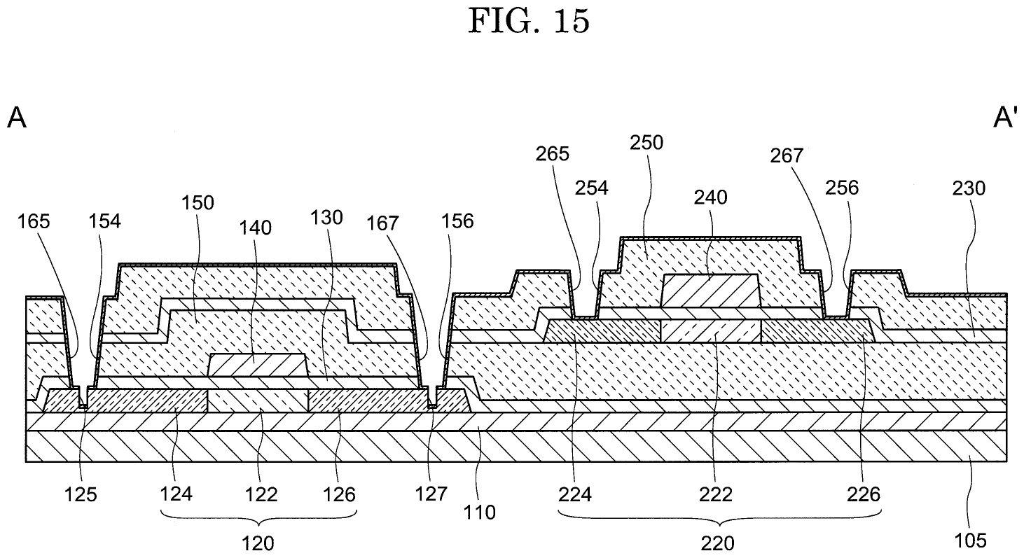

FIG. 15 is a cross-sectional view showing a process for forming a barrier metal layer in an opening in a method of manufacturing a semiconductor device according to an embodiment of the present invention. As shown in FIG. 15, a barrier metal layer including the barrier metal layers 165, 167, 265, and 267 is formed on substantially the entire surface of the substrate. The barrier metal layers 165, 167, 265, and 267 are also formed on the side surfaces and the bottom surfaces of the openings 154, 156, 254, and 256. The barrier metal layers 165, 167 include the openings in the concave part 125 and the concave part 127 of the bottom surfaces of the opening 154 and the opening 156.

Since the minimum diameter D1 at the opening end portions of the concave part 125 and the concave part 127 is small, the barrier metal layers 165, 167 are not formed on the side surfaces of the concave part 125 and the concave part 127. The barrier metal layers 165, 167 are formed on the bottom surfaces of the concave part 125 and the concave part 127. That is, the barrier metal layers 165, 167 are separated between the opening end portions and the bottom surfaces of the concave parts 125 and 127. Here, the separated indicates that the barrier metal layers 165 and 167 are discontinuous at the steps with respect to the steps of the concave parts 125 and 127.

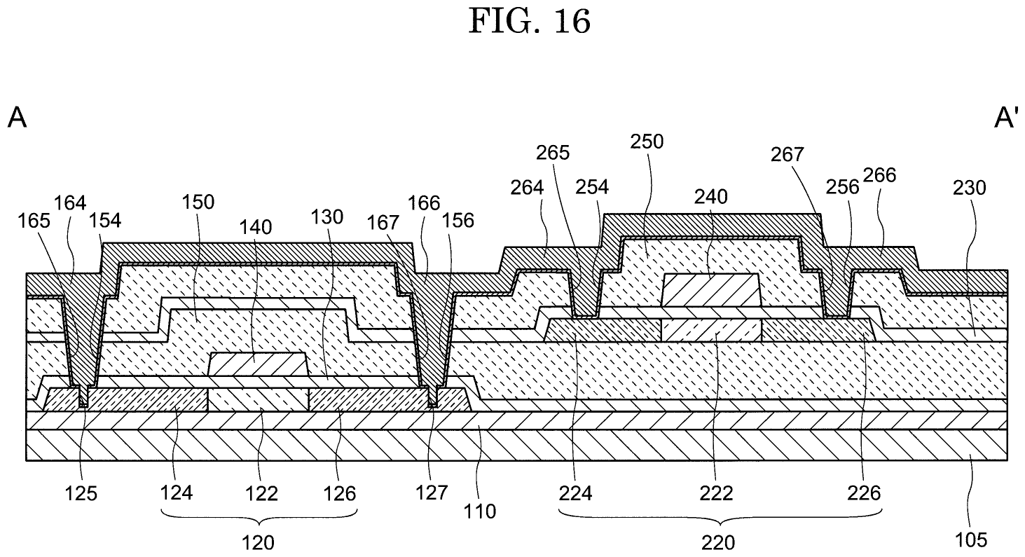

FIG. 16 is a cross-sectional view showing a process for forming a conductive layer including a source electrode and a drain electrode in a method of manufacturing a semiconductor device according to an embodiment of the present invention. As shown in FIG. 16, a conductive layer including the first source electrode 164, the first drain electrode 166, the second source electrode 264, and the second drain electrode 266 is formed on substantially the entire surface of the substrate. At this time, the first source electrode 164 and the first drain electrode 166 are arranged in the concave part 125 and the concave part 127 of the first semiconductor layer 120.

Then, the first source electrode 164, the first drain electrode 166, the second source electrode 264, and the second drain electrode 266 shown in FIGS. 1 and 2 are formed by photolithography and etching the conductive layer and the barrier metal layer including the first source electrode 164, the first drain electrode 166, the second source electrode 264, and the second drain electrode 266 shown in FIG. 16. The semiconductor device 10 according to the first embodiment of the present invention can be formed by the above manufacturing method.

### Second Embodiment

An overview of a semiconductor device according to the second embodiment will be described with reference to FIG. 17. A semiconductor device 10A according to the present embodiment is different from the semiconductor device 10 according to the first embodiment in that a concave part 125a and a concave part 127a of a first semiconductor layer 120a penetrate the first semiconductor layer 120a. In the drawings referred to in the following embodiments, the same portions as those of the first embodiment or portions having similar functions are denoted by the same numerals or the same numerals followed by the addition of an alphabet, and a repetitive description thereof is omitted.

[Structure of Semiconductor Device 10A]

FIG. 17 is an enlarged cross-sectional view of a semiconductor device according to an embodiment of the present invention. FIG. 17 shows an enlarged cross-sectional view of a connecting region between a first source electrode 164a and the first semiconductor layer 120a. A connecting region between a first drain electrode 166a and the first semiconductor layer 120a has the same configuration, and the description thereof is omitted here.

As shown in FIG. 17, the first semiconductor layer 120a is provided with the concave part 125a at a connecting part with the first source electrode 164a. The first semiconductor layer 120a is provided with the concave part 127a at the connecting part with a first drain electrode 166a. The concave part 125a and the concave part 127a penetrate the first semiconductor layer 120a and expose a base layer 110a. The first source electrode 164a and the first drain electrode 166a are arranged in the concave part 125a and the concave part 127a. A barrier metal layer 165a and a barrier metal layer 167a are arranged at bottoms of the concave part 125a and the concave part 127a. That is, the first source electrode 164a is in contact with a source region 124a of the first semiconductor layer 120a at the side surface of the concave part 125a. The first drain electrode 166a is in contact with a drain region 126a of the first semiconductor layer 120a at the side surface of the concave part 127a.

As described above, in the semiconductor device 10A according to the second embodiment of the present invention, since the concave part 125a and the concave part 127a of the first semiconductor layer 120a penetrate the first semiconductor layer 120a, the contact area between the first semiconductor layer 120a and each of the first source electrode 164a and the first drain electrode 166a is increased, and better contacts can be formed between the first source electrode 164a and the source region 124a of the first semiconductor layer 120a, and between the first drain electrode 166a and the drain region 126a of the first semiconductor layer 120a. Further, since the concave part 125a and the concave part 127a of the first semiconductor layer 120a penetrate the first semiconductor layer 120a, the physical connection strength between the first semiconductor layer 120a and each of the first source electrode 164a and the first source electrode 166a can be improved, and the reliability of the first transistor device 100a can be further improved.

### Third Embodiment

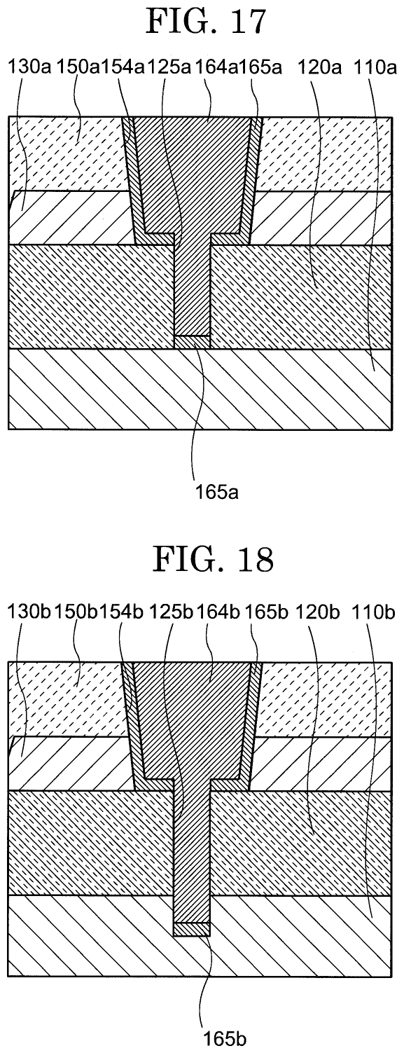

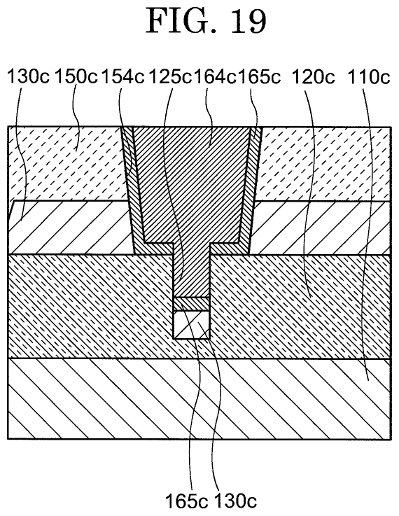

An overview of a semiconductor device according to the third embodiment will be described with reference to FIG. 18. A semiconductor device 10B according to the present embodiment is different from the semiconductor device 10 according to the first embodiment in that a concave part 125b and a concave part 127b of the first semiconductor layer 120b penetrate the first semiconductor layer 120b and in that are further connected to the concave part of a base layer 110b. In the drawings referred to in the following embodiments, the same portions as those of the first embodiment or portions having similar functions are denoted by the same numerals or the same numerals followed by the addition of an alphabet, and a repetitive description thereof is omitted.

[Structure of Semiconductor Device 10B]

FIG. 18 is an enlarged cross-sectional view of a semiconductor device according to an embodiment of the present invention. FIG. 18 shows an enlarged cross-sectional view of a connecting region between a first source electrode 164b and the first semiconductor layer 120b. A connecting region between a first drain electrode 166b and the first semiconductor layer 120b has the same construction, and the description thereof is omitted here.

As shown in FIG. 18, the first semiconductor layer 120b is provided with the concave part 125b at a connecting part with the first source electrode 164b. The first semiconductor layer 120b is provided with the concave part 127b at the connecting part with the first drain electrode 166b. The concave part 125b and the concave part 127b penetrate the first semiconductor layer 120b and are connected to the concave part of the base layer 110b. The through hole of the first semiconductor layer 120b and the concave part of the base layer 110b are integrated, and both are included in the concave part 125b and the concave part 127b. The concave part 125b and the concave part 127b are arranged with the first source electrode 164b and the first drain electrode 166b. A barrier metal layer 165b and a barrier metal layer 167b are arranged at the bottoms of the concave part 125b and the concave part 127b. That is, the first source electrode 164b is in contact with a source region 124b of the first semiconductor layer 120b at the side surface of the concave part 125b. The first drain electrode 166b is in contact with a drain region 126b of the first semiconductor layer 120b at the side surface of the concave part 127b.

As described above, in the semiconductor device 10B according to the third embodiment of the present invention, since the concave part 125b and the concave part 127b of the first semiconductor layer 120b penetrate the first semiconductor layer 120b, the contact area between the first semiconductor layer 120b and each of the first source electrode 164b and the first drain electrode 166b is increased, and better contacts can be formed between the first source electrode 164b and the source region 124b of the first semiconductor layer 120b, and between the first drain electrode 166b and the drain region 126b of the first semiconductor layer 120b. Further, since the concave part 125b and the concave part 127b of the first semiconductor layer 120b penetrate the first semiconductor layer 120b and are connected to the base layer 110b, the physical connection strength between the first semiconductor layer 120b and each of the first source electrode 164b and the first drain electrode 166b can be improved, and the reliability of the first transistor element 100b can be further improved.

### Fourth Embodiment

An overview of a semiconductor device according to the fourth embodiment will be described with reference to FIG. 19. A semiconductor device 100 according to the present embodiment is different from the semiconductor device 10 according to the first embodiment in that a first gate insulating layer 130c is arranged in a concave part 125c and a concave part 127c of a first semiconductor layer 120c. In the drawings referred to in the following embodiments, the same portions as those of the first embodiment or portions having similar functions are denoted by the same numerals or the same numerals followed by the addition of an alphabet, and a repetitive description thereof is omitted.

[Structure of Semiconductor Device 100]

FIG. 19 is an enlarged cross-sectional view of a semiconductor device according to an embodiment of the present invention. FIG. 19 shows an enlarged cross-sectional view of a connecting region between a first source electrode 164c and the first semiconductor layer 120c. The connecting region between a first drain electrode 166c and the first semiconductor layer 120c has the same structure, and therefore the description thereof is omitted here.

As shown in FIG. 19, the first semiconductor layer 120c is provided with the concave part 125c at a connecting part with the first source electrode 164c. The first semiconductor layer 120c is provided with the concave part 127c at the connecting part with the first drain electrode 166c. The first source electrode 164c and the first drain electrode 166c are arranged in the concave part 125c and the concave part 127c. In the concave part 125c and the concave part 127c, a barrier metal layer 165c and a barrier metal layer 167c are arranged below the first source electrode 164c and the first drain electrode 166c. The first gate insulating layer 130c is arranged at the bottoms of the concave part 125c and the concave part 127c. That is, the first source electrode 164c is in contact with a source region 124c of the first semiconductor layer 120c at the side surface of the concave part 125c. The first drain electrode 166c is in contact with a drain region 126c of the first semiconductor layer 120 cat the side surface of the concave part 127c.

As described above, in the semiconductor device 10C according to the fourth embodiment, since the first semiconductor layer 120c has the concave part 125c and the concave part 127c, the contact area between the first semiconductor layer 120c and each of the first source electrode 164c and the first drain electrode 166c is increased, and better contacts can be formed between the first source electrode 164c and the source region 124c of the first semiconductor layer 120c, and between the first drain electrode 166c and the drain region 126c of the first semiconductor layer 120c. In addition, since the first semiconductor layer 120c has the concave part 125c and the concave part 127c, the physical connection strength between the first semiconductor layer 120c and each of the first source electrode 164c and the first source electrode 166c can be improved, and the reliability of the first transistor device 100c can be improved.

### Fifth Embodiment

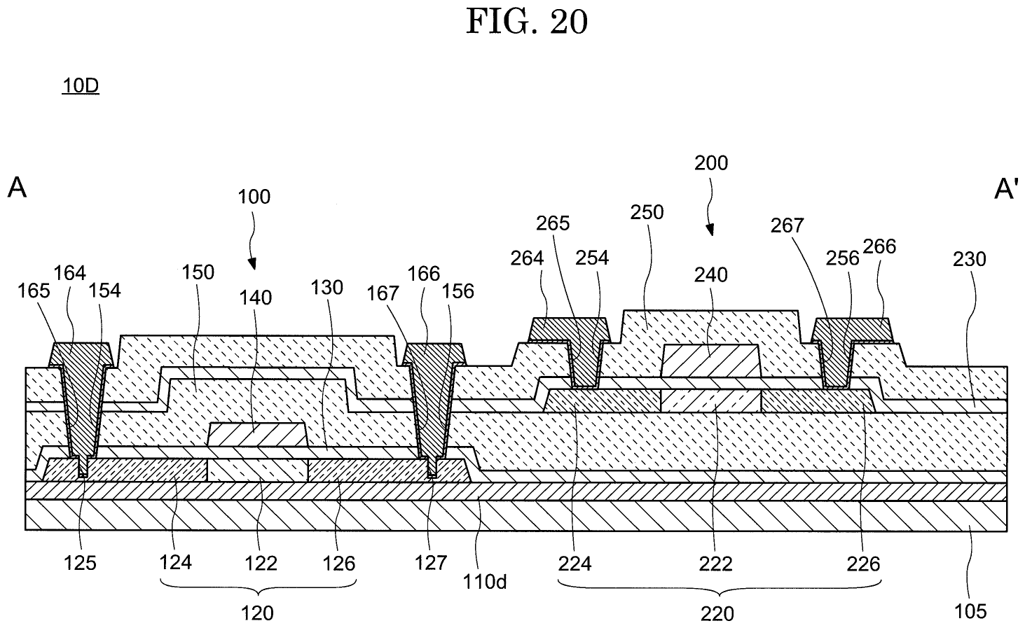

An overview of a semiconductor device 10D according to the fifth embodiment will be described with reference to FIG. 20. The semiconductor device 10D according to the present embodiment is different from the semiconductor device 10 according to the first embodiment in that the properties of a base layer 110d are different. In the drawings referred to in the following embodiments, the same portions as those of the first embodiment or portions having similar functions are denoted by the same numerals or the same numerals followed by the addition of an alphabet, and a repetitive description thereof is omitted.

[Structure of Semiconductor Device 10D]

FIG. 20 is a cross-sectional view showing an overview of a semiconductor device according to an embodiment of the present invention. The semiconductor device 10D shown in FIG. 20 is similar to the semiconductor device 10 shown in FIG. 2, but the semiconductor device 10D is different from the semiconductor device 10 in the properties of the base layer 110d. The base layer 110d of the semiconductor device 10D according to the present embodiment has a lower etching rate than a first gate insulating layer 130d. A material of the base layer 110d may be the same as the material of the first gate insulating layer 130d, wherein the film quality of the base layer 110d may be denser than the film quality of the first gate insulating layer 130d. With such configuration, the base layer 110d can function as an etching stopper of the first gate insulating layer 130d in the process for forming the opening in the method of manufacturing the semiconductor device according to the present embodiment. In particular, in the configurations of the second embodiment and the third embodiment in which a concave part 125d and a concave part 127d penetrate the first semiconductor layer 120d, it is possible to suppress the base layer 110d from being eroded.

### Sixth Embodiment

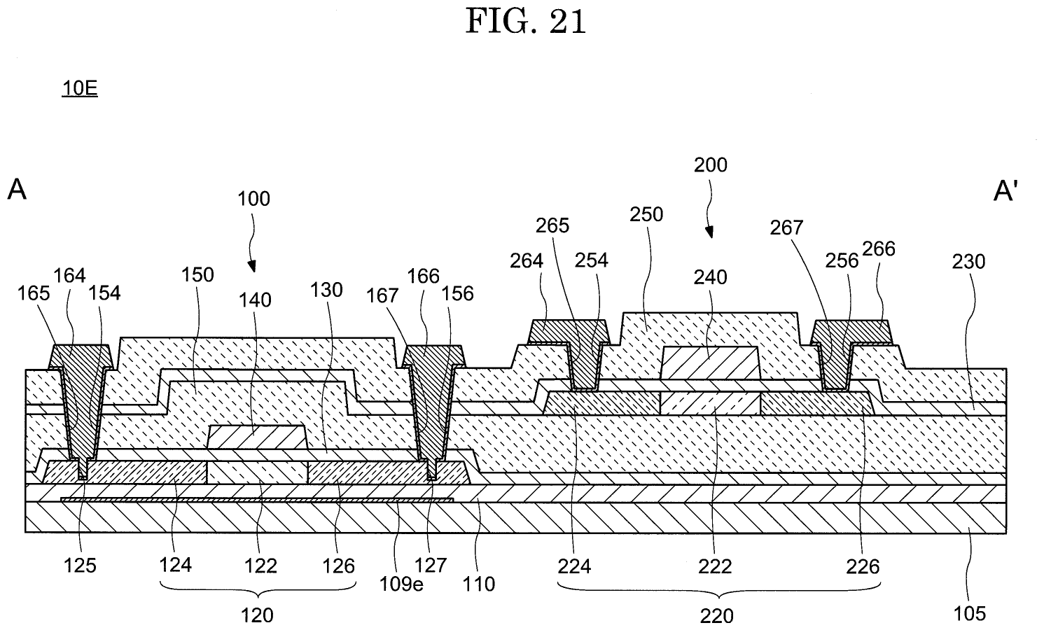

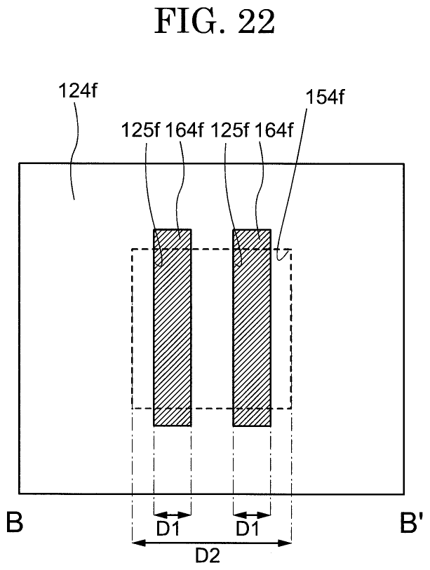

An overview of a semiconductor device 10E according to the sixth embodiment will be described with reference to FIG. 21. The semiconductor device 10E according to the present embodiment is different from the semiconductor device 10 according to the first embodiment in that it further includes a metal layer 109e between a substrate layer 105e and a base layer 110e. In the drawings referred to in the following embodiments, the same portions as those of the first embodiment or portions having similar functions are denoted by the same numerals or the same numerals followed by the addition of an alphabet, and a repetitive description thereof is omitted.

[Structure of Semiconductor Device 10E]

FIG. 21 is a cross-sectional view showing an overview of a semiconductor device according to an embodiment of the present invention. The semiconductor device 10E shown in FIG. 21 is similar to the semiconductor device 10 shown in FIG. 2, but the semiconductor device 10E is different from the semiconductor device 10 in that it further includes the metal layer 109e between the substrate 105e and the base layer 110e. With such a configuration, the metal layer 109e below the base layer 110e can function as an etching stopper of a first gate insulating layer 130e in the process for forming the opening in the method of manufacturing the semiconductor device according to the present embodiment. In particular, in the configurations of the second embodiment and the third embodiment in which a concave part 125e and a concave part 127e penetrate the first semiconductor layer 120e, it is possible to suppress the substrate 105e from being exposed due to the erosion of the base layer 110e.

### Modified Example 1

An overview of a semiconductor device according to a modified example of the present embodiment will be described with reference to FIG. 22. A semiconductor device 10F according to the present modified example is different from the semiconductor device 10 according to the first embodiment in that a plurality of concave parts 125f and concave parts 127f of the first semiconductor layer 120f are arranged. In the drawings referred to in the modified examples 1 to 3 below, the same portions or portions having the same functions as those of the first embodiment are denoted by the same numerals or the same numerals followed by the addition of an alphabet, and a repetitive description thereof will be omitted.

[Structure of Semiconductor Device 10F]

FIG. 22 is an enlarged cross-sectional view of a semiconductor device according to a modified example of the present invention. FIG. 22 shows an enlarged cross-sectional view of a connecting region between a first source electrode 164f and the first semiconductor layer 120f. A connecting region between a first drain electrode 166f and the first semiconductor layer 120f has the same configuration, and therefore, the description thereof is omitted here.

As shown in FIG. 22, a source region 124f of the first semiconductor layer 120 f is provided with a plurality of concave parts 125f at the connecting part with the first source electrode 164f. A drain region 126f of the first semiconductor layer 120f is provided with a plurality of concave parts 127f at the connecting part with the first drain electrode 166f. The plurality of concave parts 125f and concave parts 127f are separated from each other. The first source electrode 164f and the first drain electrode 166f are arranged in the concave part 125f and the concave part 127f. The minimum diameter D1 at the opening ends of the concave part 125f and the concave part 127f is smaller than the minimum diameter D2 of an opening 154f and an opening 156f. Therefore, a barrier metal layer 165f and a barrier metal layer 167f are arranged at the bottoms of the plurality of the concave parts 125f and 127f. However, the barrier metal layer 165f and the barrier metal layer 167f are not arranged on the side surfaces of the plurality of the concave parts 125f and 127f, and are separated from each other at the opening end portions and the bottoms. Therefore, the first source electrode 164f is in contact with the source region 124f of the first semiconductor layer 120f at the side surfaces of the plurality of concave parts 125f. The first drain electrode 166f is in contact with the drain region 126f of the first semiconductor layer 120f at the side surfaces of the plurality of the concave parts 127f.

As described above, in the semiconductor device 10F according to a modified example of the present invention, since the plurality of concave parts 125f concave parts 127f of the first semiconductor layer 120f is arranged, the contact area between the first semiconductor layer 120f and each of the first source electrode 164f and the first drain electrode 166f is further increased, and better contacts can be formed between the first source electrode 164f and the source region 124f of the first semiconductor layer 120f, and between the first drain electrode 166f and the drain region 126f of the first semiconductor layer 120f. Further, since the plurality of the concave parts 125f and concave parts 127f of the first semiconductor layer 120f are arranged, the physical connection strength between the first semiconductor layer 120f and each of the first source electrode 164f and the first source electrode 166f can be improved, and the reliability of the first transistor device 100f can be further improved.

### Modified Example 2

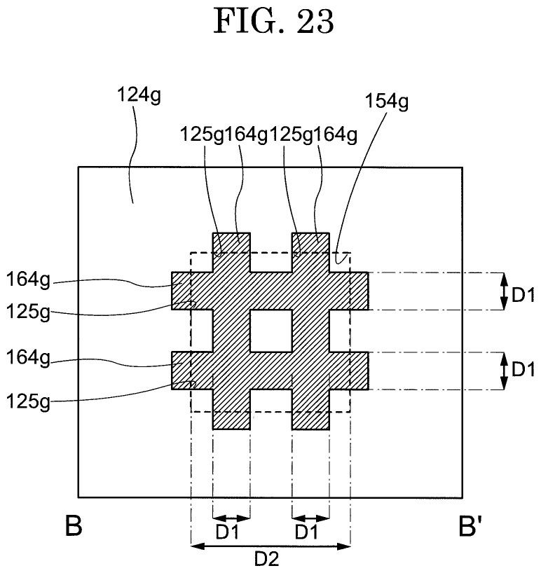

An overview of a semiconductor device according to a modified example of the present embodiment will be described with reference to FIG. 23. A semiconductor device 10G according to a modified example is different from the semiconductor device 10 according to the first embodiment in that a plurality of concave parts 125g and concave parts 127g of the semiconductor layer 120g is arranged and is connected.

[Structure of Semiconductor Device 10G]

FIG. 23 is an enlarged cross-sectional view of a semiconductor device according to a modified example of the present invention. FIG. 23 shows an enlarged cross-sectional view of a connecting region between a first source electrode 164g and the first semiconductor layer 120g. A connecting region between the first drain electrode 166g and the first semiconductor layer 120g has the same structure, and therefore the description thereof is omitted here.

As shown in FIG. 23, the source region 124g of the first semiconductor layer 120g is provided with a plurality of concave parts 125g at the connecting part with the first source electrode 164g. A drain region 126g of the first semiconductor layer 120g is provided with a plurality of concave parts 127g at the connecting part with the first drain electrode 166g. The plurality of concave parts 125g and concave parts 127g are connected to each other. The first source electrode 164g and the first drain electrode 166g are arranged in the plurality of concave pars 125g and concave parts 127g. The minimum diameter D1 at the opening end portions of the concave part 125g and the concave part 127g is smaller than the minimum diameter D2 of an opening 154g and an opening 156g. Therefore, a barrier metal layer 165g and a barrier metal layer 167g are arranged at the bottoms of the plurality of concave parts 125g and concave parts 127g. However, the barrier metal layer 165g and the barrier metal layer 167g are not arranged on the side surfaces of the plurality of concave parts 125g and concave parts 127g, and are separated from each other at the opening end portions and the bottoms. Therefore, the first source electrode 164g is in contact with the source region 124g of the first semiconductor layer 120g at the side surfaces of the plurality of concave parts 125g. The first drain electrode 166g is in contact with the drain region 126g of the first semiconductor layer 120g at the side surfaces of the plurality of concave parts 127g.

As described above, in the semiconductor device 10G according to a modified example of the present invention, since the plurality of concave parts 125g and concave parts 127g of the first semiconductor layer 120g are arranged and connected to each other, the contact area between the first semiconductor layer 120g and each of the first source electrode 164g and the first drain electrode 166g is further increased, and better contacts can be formed between the first source electrode 164g and the source region 124g of the first semiconductor layer 120g, and between the first drain electrode 166g and the drain region 126g of the first semiconductor layer 120g. In addition, since the plurality of concave parts 125g and concave parts 127g of the first semiconductor layer 120g are arranged and connected to each other, the physical connection strength between the first semiconductor layer 120g and each of the first source electrode 164g and the first drain electrode 166g can be further improved, and the reliability of the first transistor device 100g can be further improved.

### Modified Example 3

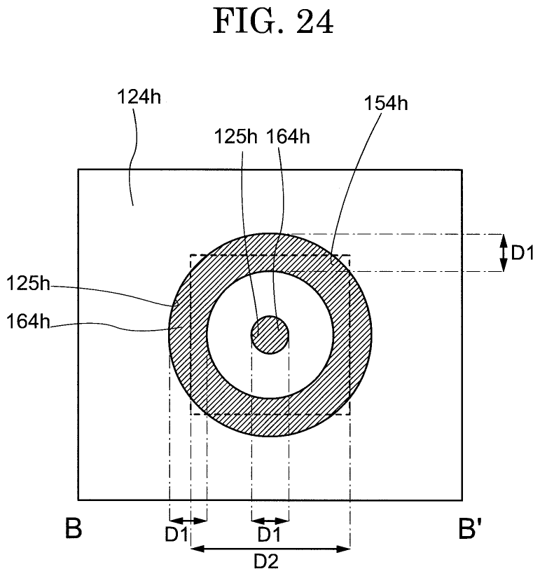

An overview of a semiconductor device according to a modified example of the present embodiment will be described with reference to FIG. 24. A semiconductor device 10H according to the present modified example is different from the semiconductor device 10 according to the first embodiment in that a plurality of concave parts 125h and concave parts 127h of the first semiconductor layer 120h are arranged, and the shapes thereof are different.

[Structure of Semiconductor Device 10H]

FIG. 24 is an enlarged cross-sectional view of a semiconductor device according to a modified example of the present invention. FIG. 24 shows an enlarged cross-sectional view of a connecting region between a first source electrode 164h and the first semiconductor layer 120h. The connecting region between a first drain electrode 166h and the first semiconductor layer 120h has the same structure, and therefore the description thereof is omitted here.

As shown in FIG. 24, a source region 124h of the first semiconductor layer 120h is provided with the plurality of concave parts 125h at the connecting part with the first source electrode 164h. A drain region 126h of the first semiconductor layer 120h is provided with the plurality of concave parts 127h at the connecting part with the first drain electrode 166h. The plurality of concave parts 125h and concave parts 127h are separated from each other. The first source electrode 164h and the first drain electrode 166h are arranged in the concave part 125h and the concave part 127h. The minimum diameter D1 at the opening end portions of the concave part 125h and the concave part 127h is smaller than the minimum diameter D2 of an opening 154h and an opening 156h. Therefore, a barrier metal layer 165h and a barrier metal layer 167h are arranged at the bottoms of the plurality of concave parts 125h and concave parts 127h. However, the barrier metal layer 165h and the barrier metal layer 167h are not arranged on the side surfaces of the plurality of concave parts 125h and concave parts 127h, and are separated from each other at the opening end portions and the bottoms. Therefore, the first source electrode 164h is in contact with the source region 124h of the first semiconductor layer 120h at the side surfaces of the plurality of concave parts 125h. The first drain electrode 166h is in contact with the drain region 126h of the first semiconductor layer 120h at the side surfaces of the plurality of concave parts 127h.

As described above, in the semiconductor device 10H according to a modified example of the present invention, since the plurality of concave parts 125h and concave parts 127h of the first semiconductor layer 120h is arranged, the contact area between the first semiconductor layer 120h and each of the first source electrode 164h and the first drain electrode 166h is further increased, better contacts can be formed between the first source electrode 164h and the source region 124h of the first semiconductor layer 120h, and between the first drain electrode 166h and the drain region 126h of the first semiconductor layer 120h. Further, since the plurality of concave parts 125h and concave parts 127h of the first semiconductor layer 120h are arranged and connected to each other, the physical connection strength between the first semiconductor layer 120h and each of the first source electrode 164h and the first source electrode 166h can be further improved, and the reliability of the first transistor device 100h can be further improved.

The present invention is not limited to the above embodiments, and can be appropriately modified within a range not departing from the spirit thereof. The embodiments can be combined as appropriate.

What is claimed is:

1. A semiconductor device comprising a first circuit element, the first circuit element comprising:
a first semiconductor layer having a concave part;
a first insulating layer arranged above the first semiconductor layer, the first insulating layer having a first through hole in a region overlapping with the concave part; and
a first conductive layer arranged in the concave part and the first through hole.

2. The semiconductor device according to claim 1, wherein the first conductive layer is in contact with a side surface of the concave part.

3. The semiconductor device according to claim 2, wherein a minimum diameter at the open end of the concave part is smaller than a minimum diameter of the first through hole.

4. The semiconductor device according to claim 1, wherein
the first circuit element further comprises a second conductive layer arranged between the first semiconductor layer and the first conductive layer, and
the second conductive layer has an opening at the concave part.

5. The semiconductor device according to claim 4, wherein the second conductive layer is separated on a side surface of the concave part.

6. The semiconductor device according to claim 4, wherein the second conductive layer is further arranged on a bottom surface of the concave part.

7. The semiconductor device according to claim 4, the semiconductor device further comprising a second circuit element, the second circuit element comprising:
a second semiconductor layer arranged below the second conductive layer; and
a third conductive layer arranged above the second conductive layer, the third conductive layer connected to the second semiconductor layer via the second conductive layer.

8. The semiconductor device according to claim 7, wherein the second circuit element further includes a second insulating layer, and the second insulating layer is arranged above the second semiconductor layer and has a second through hole in a region overlapping with the first through hole.

9. The semiconductor device according to claim 8, wherein the first conductive layer and the third conductive layer include same material.

10. The semiconductor device according to claim 8, wherein the second semiconductor layer includes an oxide semiconductor, and the first semiconductor layer and the second semiconductor layer include different materials.

11. The semiconductor device according to claim 8, wherein the first circuit element further includes a first gate electrode arranged between the first semiconductor layer and the first insulating layer, and a first gate insulating layer arranged between the first semiconductor layer and the first gate electrode.

12. The semiconductor device according to claim 8, wherein the second circuit element further includes a second gate electrode arranged between the second semiconductor layer and the second insulating layer, and a second gate insulating layer arranged between the second semiconductor layer and the second gate electrode.

13. The semiconductor device according to claim 7, wherein the second semiconductor layer is arranged above the first insulating layer.

14. The semiconductor device according to claim 4, wherein the first conductive layer contains Ti, and the second conductive layer contains TiN.

15. The semiconductor device according to claim 1, wherein the concave part penetrates the first semiconductor layer.

16. The semiconductor device according to claim 1, wherein the first circuit element is arranged below the first semiconductor layer, and the first circuit element further includes a protective layer overlapping with the concave part.

17. A method of manufacturing a semiconductor device, the method comprising:
forming a first semiconductor layer having a concave part on a substrate;
forming a first insulating layer on the first semiconductor layer;
forming a first through hole in a region of the first insulating layer overlapping with the concave part; and
forming a first conductive layer arranged in the concave part and the first through hole.

18. The method of manufacturing a semiconductor device according to claim 17, the method further comprising:
forming a second conductive layer having an opening at the concave part before forming the first conductive layer.

19. The method of manufacturing a semiconductor device according to claim 18, wherein the second conductive layer is separated on a side surface of the concave part.

20. The method for manufacturing a semiconductor device according to claim 18, wherein the second conductive layer is formed on the bottom surface of the concave part.

21. The method of manufacturing a semiconductor device according to claim 18, the method further comprising:
forming a second semiconductor layer after forming the first insulating layer; and
forming a third conductive layer after forming the second conductive layer, the third conductive layer connected to the second semiconductor layer via the second conductive layer together with the first conductive layer.

22. The method of manufacturing a semiconductor device according to claim 21, the method further comprising:
forming a second insulating layer after forming the second semiconductor layer; and
forming a second through hole on the second insulating layer that exposes the second semiconductor layer, forming a first through hole connecting to the concave part on the first insulating layer and the second insulating layer, and forming a third through hole connecting to the first through hole on the first insulating layer and the second insulating layer before forming the second conductive layer.

23. The method for manufacturing a semiconductor device according to claim 21, wherein
the second semiconductor layer is formed using a material containing an oxide semiconductor, and
the first semiconductor layer and the second semiconductor layer are formed by using different materials.

24. The method for manufacturing a semiconductor device according to claim 18, wherein
the first conductive layer is formed by using a material containing Ti, and
the second conductive layer is formed by using a material containing TiN.
